(19) United States
(12) Patent Application Publication
(10) Pub. No.: US 2012/0121061 A1
(43) Pub. Date: May 17, 2012

(54) SHIFT REGISTER

(75) Inventors: Mayuko Sakamoto, Osaka-shi (JP); Yasuaki Iwase, Osaka-shi (JP)

(73) Assignee: SHARP KABUSHIKI KAISHA, Osaka-shi, Osaka (JP)

(21) Appl. No.: 13/383,422

(22) PCT Filed: Feb. 1, 2010
(86) PCT No.: PCT/JP2010/000568

§ 371 Date: Jan. 11, 2012

(30) Foreign Application Priority Data
Jul. 15, 2009 (JP) 2009-166702

(51) Int. Cl. G11C 19/00; H01L 21/66

(52) U.S. Cl. 377/64; 438/4; 257/E21.521

(57) ABSTRACT

A shift register according to the present invention is supported on an insulating substrate and has multiple stages that sequentially shift an output signal from one stage to the next. Each of those stages has a circuit 20 including multiple thin-film transistors. The multiple thin-film transistors include a first thin-film transistor MK, which influences the operation of the circuit, and a second thin-film transistor MK_YOBI, which has at least one floating terminal and other terminal(s) that is/are connected to corresponding terminal(s) of the first thin-film transistor MK. The at least one floating terminal is arranged so as to be connectible to a predetermined line N2. Consequently, the yield of shift registers with a monolithic gate driver can be increased.

### TECHNICAL FIELD

The present invention relates to a shift register and more particularly relates to a shift register that forms part of the active-matrix substrate of an LCD panel or an organic EL display panel.

### BACKGROUND ART

Recently, liquid crystal display devices and organic EL display devices, in which a thin-film transistor (TFT) is provided for each pixel, have become immensely popular. A TFT is fabricated using a semiconductor layer that has been formed on a substrate such as a glass substrate. And a substrate on which TFTs have been formed is called an active-matrix substrate.

There are two types of TFTs that have been used extensively. One of the two types of TFTs uses an amorphous silicon layer as its active layer (and will be referred to herein as “amorphous silicon TFTs”). The other type of TFTs uses a polysilicon layer as its active layer (and will be referred to herein as “polysilicon TFTs”).

Since a polysilicon film achieves a higher carrier mobility than an amorphous silicon film does, a polysilicon TFT makes a greater amount of ON-state current flow, and can operate faster, than an amorphous silicon TFT does. That is why in some display panels recently developed, polysilicon TFTs are used as not just TFTs for pixels but also some or all of the TFTs that form a peripheral circuit such as a driver. Such a driver that has been formed on an insulating substrate (which is typically a glass substrate) of a display panel is sometimes called a “monolithic driver”. Drivers include a gate driver and a source driver, only one of which may be called a monolithic driver. In this description, a display panel refers herein to a portion of a liquid crystal display device or an organic EL display device that has a display area and does not include the backlight or bezel of the liquid crystal display device.

In this description, a display panel with a monolithic gate driver will be referred to herein as a “gate driver monolithic panel”. Such a gate driver monolithic panel includes a display area in which a number of pixels are arranged (which will be sometimes referred to herein as a “pixel area”) and a frame area in which drivers such as a gate driver have been formed (and which will be referred to herein as a “surrounding area”).

Meanwhile, a display panel sometimes has a repair line to repair disconnection that was made during the manufacturing process. For example, Patent Document No. 1 proposes providing a repair line to repair a signal line. On the other hand, Patent Document No. 2 proposes repairing a data line disconnection by providing a dummy buffer section for a data driver in the frame area.

### CITATION LIST

### Patent Literature

Patent Document No. 1: Japanese Patent Application Laid-Open Publication No. 2008-165237
Patent Document No. 2: Japanese Patent Application Laid-Open Publication No. 2008-26900

### SUMMARY OF INVENTION

### Technical Problem

In a gate driver monolithic panel, the frame area (and its shift register, among other things) usually has a higher pattern density than the pixel area for the following reasons.

Specifically, to increase the contrast ratio on the display screen, the pixel area preferably has its aperture ratio increased. In that case, however, the percentage of a unit area accounted for by lines and elements decreases. In the frame area, on the other hand, a shift register and other drivers should be laid out in as narrow a space as possible to cut down the space allocated to the frame area (which will be referred to herein as “frame narrowing”). That is why those lines and elements are preferably arranged as densely as possible (which will be referred to herein as a “most densely packed structure”) and the percentage of a unit area accounted for by those lines and elements must be increased significantly.

However, if the shift register had such a high pattern density, the chances of generating disconnection, leakage and other defects on the shift register during the manufacturing process of a gate driver monolithic panel would rise.

Once a minor defect were generated in the shift register albeit locally, sometimes the signal could not be transmitted no farther than the spot with that defect, thus making the entire panel defective. Since a single local defect makes the entire panel unusable, the yield will decrease steeply.

It is therefore an object of the present invention to increase the yield by repairing a disconnection that has been made on the shift register of a monolithic gate driver.

### Solution to Problem

A shift register according to the present invention is supported on an insulating substrate and has multiple stages that sequentially shift an output signal from one stage to the next. Each of those stages has a circuit including multiple thin-film transistors. The multiple thin-film transistors include a first thin-film transistor, which influences the operation of the circuit, and a second thin-film transistor, which has at least one floating terminal and other terminal(s) that is/are connected to corresponding terminal(s) of the first thin-film transistor. The at least one floating terminal is arranged so as to be connectible to a predetermined line.

In one preferred embodiment, when viewed from over the substrate, the channel regions of the first and second thin-film transistors have substantially the same shape.

In another preferred embodiment, the first and second thin-film transistors have a structure in which one of their source and drain electrodes is connected to their gate electrode. The other of the source and drain electrodes of the second thin-film transistor is floating.

In still another preferred embodiment, an extended portion of the at least one floating terminal of the second thin-film transistor and an extended portion of a terminal of the first thin-film transistor, which corresponds to the floating terminal, overlap with each other without being connected together.

When viewed from over the substrate, the size of the overlapping portion may be bigger than 10 μm×10 μm.

If the three terminals of the first thin-film transistor are identified by 1A, 1B and 1C, respectively, the three terminals of the second thin-film transistor are identified by 2A, 2B and 2C, respectively, and the terminals 2A, 2B and 2C correspond to the terminals 1A, 1B and 1C, respectively, then the terminals 2A, 1A, 1C and 2C may be made of a first conductor film, the terminals 2B and 1B may be made of a second conductor film, which is different from the first conductor film, and at least the terminal 2C may be connected to the terminal 1C.

The terminal 2B may be connected to the terminal 1B.

It is preferred that no other thin-film transistors be interposed between the first and second thin-film transistors.

In one preferred embodiment, the first and second thin-film transistors have the same number of channels, which is equal to or smaller than five.

The number of the channels may be one.

A terminal of the first thin-film transistor that corresponds to the floating terminal preferably has an extended portion, which preferably has a length of 100 μm or more.

Another shift register according to the present invention is supported on an insulating substrate and has multiple stages, which sequentially shift an output signal from one stage to the next and at least one of which has a circuit including multiple thin-film transistors. The multiple thin-film transistors include a thin-film transistor M1, which influences the operation of the circuit, and a thin-film transistor M2, which has at least one floating terminal and other terminal(s) that is/are connected to corresponding terminal(s) of the thin-film transistor M1. An extended portion of that terminal of the thin-film transistor M1 that corresponds to the floating terminal overlaps with a predetermined line, and the overlapping portion has been subjected to a melt treatment, thereby connecting the extended portion of the thin-film transistor M1 and the predetermined line together.

An active-matrix substrate according to the present invention includes a shift register according to any of the preferred embodiments of the present invention described above.

A display panel according to the present invention includes a shift register according to any of the preferred embodiments of the present invention described above.

A shift register fabricating method according to the present invention is designed to fabricate a shift register according to the preferred embodiment of the present invention described above. The method includes the steps of: inspecting the first thin-film transistor of the circuit for defects; and if any defect has been detected in the step of inspecting, performing a repair process by disconnecting the first thin-film transistor from the circuit and by connecting the floating terminal of the second thin-film transistor to a predetermined line. The repair process includes subjecting the overlapping portion to a melt treatment and connecting the floating terminal of the second thin-film transistor to the predetermined line.

### Advantageous Effects of Invention

According to the present invention, even if disconnection, leakage current or any other defect has been caused in a shift register during the manufacturing process of a gate driver monolithic panel, the shift register can still be operated properly with the defect repaired. Consequently, the yield of gate driver monolithic panels can be increased.

### BRIEF DESCRIPTION OF DRAWINGS

FIG. 1(a) is a schematic plan view illustrating an LCD panel 100 as a specific preferred embodiment of the present invention, while FIG. 1(b) schematically illustrates the structure of one pixel thereof.

FIG. 2(a) is a block diagram illustrating a configuration for a shift register 110A included in a gate driver 110 and FIG. 2(b) is a plan view illustrating a much simplified version of the configuration shown in FIG. 2(a).

FIG. 3 illustrates the waveforms of clock signals supplied to the shift register 110A.

FIG. 4 is a schematic plan view illustrating an LCD panel as an alternative preferred embodiment of the present invention.

FIG. 5 illustrates a circuit 10 on one stage of a shift register 110A as a comparative example in which no TFT for repair is provided.

FIG. 6 illustrate the waveforms of input and output signals at respective stages of the shift register 110A along with the voltage waveforms at nodes N1 and N2.

FIG. 7(a) illustrates an exemplary configuration for a circuit 20 on one stage of a shift register as a first preferred embodiment of the present invention. FIG. 7(b) is a schematic plan view illustrating, on a larger scale, the dotted-line portion of the circuit 20 that includes a TFT for repair.

FIGS. 8(a) through 8(c) are plan views illustrating configurations for TFTs for use in the circuit 20.

FIG. 9 illustrates how to repair the TFT shown in FIG. 8(c) without using a TFT for repair in a situation where some defect was caused in the TFT.

FIG. 10(a) illustrates an exemplary configuration for a circuit 50 on one stage of a shift register as a second preferred embodiment of the present invention. FIG. 10(b) is a schematic plan view illustrating, on a larger scale, the dotted-line portion of the circuit 50 that includes a TFT for repair.

FIG. 11 illustrates the layout of a portion of the circuit 50 shown in FIG. 10(a).

### DESCRIPTION OF EMBODIMENTS

The present invention is characterized by providing not only a TFT that influences the operation of a circuit (which will sometimes be referred to herein as a “first TFT”) but also a TFT for repair (which will sometimes be referred to herein as a “second TFT”) for a shift register. It is preferred that the second TFT be arranged adjacent to the first TFT and that no other TFTs be interposed between the first and second TFTs. And the first and second TFTs preferably have the same configuration (in terms of the shape of their semiconductor layer and the number of their channels).

A shift register according to the present invention is applicable effectively to a gate driver monolithic panel. In that case, the second TFT is also arranged in a shift register circuit region of the monolithic gate driver.

Hereinafter, preferred embodiments of the present invention will be described in detail.

### Embodiment 1

Hereinafter, a First Preferred Embodiment of a Shift register according to the present invention will be described with reference to the accompanying drawings. The shift register to be described below is supposed to form an integral part of an LCD panel (i.e., a monolithic LCD panel will be described). However, this is just an example of the present invention and the present invention is in no way limited to that specific preferred embodiment.

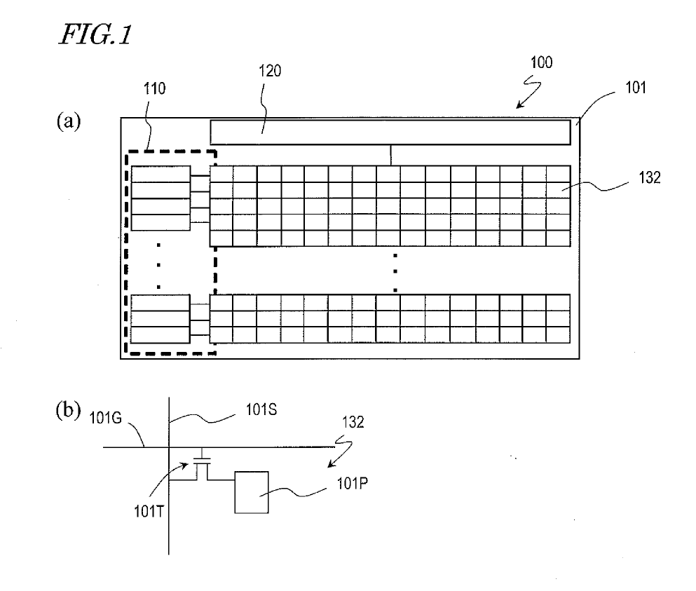

FIG. 1(a) is a schematic plan view illustrating an LCD panel 100 as a specific preferred embodiment of the present invention, while FIG. 1(b) schematically illustrates the structure of one pixel thereof. In FIG. 1(a), illustrated is only the structure of the active-matrix substrate 101 of the LCD panel 100 with the illustration of its liquid crystal layer and counter substrate omitted. By providing a backlight, a power supply and other members for this LCD panel 100, a liquid crystal display device can be obtained.

On the active-matrix substrate 101, a gate driver 110 and a source driver 120 are arranged so as to form integral parts thereof. In the display area of the LCD panel 100, a number of pixels are arranged. A portion of the active-matrix substrate 101 that covers one of those pixels is identified by the reference numeral 132. It should be noted that the source driver 120 does not always have to form an integral part of the active-matrix substrate 101. Optionally, a source driver IC that has been fabricated separately may be introduced there by a known method, too.

As shown in FIG. 1(b), the active-matrix substrate 101 includes a pixel electrode 101P, which is associated with one pixel of the LCD panel 100. The pixel electrode 101P is connected to a source bus line 1015 through a pixel TFT 101T. The gate electrode of the TFT 101T is connected to a gate bus line 101G.

The gate bus line 101G is connected to the output of the gate driver 110 so that the display area is scanned line sequentially. On the other hand, the source bus line 1015 is connected to the output of the source driver 120 and is supplied with a display signal voltage (grayscale voltage).

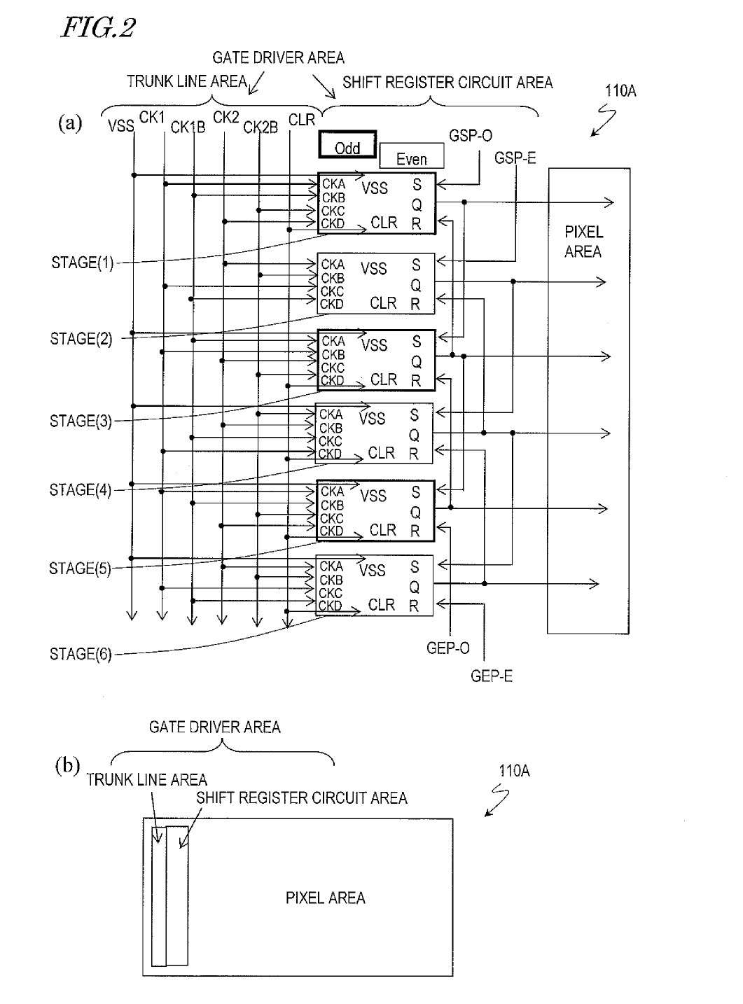

Next, look at FIG. 2(a), which is a block diagram illustrating a configuration for a shift register 110A included in the gate driver 110. The shift register 110A is supported on an insulating substrate such as a glass substrate that forms the base of the active-matrix substrate 101. TFTs that form this shift register 110A and pixel TFTs 101T that are arranged in the display area of the active-matrix substrate 110 are preferably made by carrying out the same process.

In FIG. 2(a), illustrated schematically are only the first through sixth stages STAGE(1) through STAGE(6) of the multiple stages (first through Nth stages) that the shift register 110A has. All of these stages have substantially the same structure and are cascaded together. The output of each stage of the shift register 110A is supplied to its associated gate bus line 101G in the pixel area of the LCD panel 100. Such a shift register 110A is disclosed in Japanese Patent Application No. 2008-314501, which was filed by the Applicant of the present application and the disclosure of which is hereby incorporated by reference.

Each stage of the shift register 110A includes an input terminal that receives a set signal S, an input terminal that receives a reset signal R, an output terminal that delivers an output signal Q, and input terminals that receive four clock signals CKA, CKB, CKC and CKD that have mutually different phases. A gate start pulse GSP-O is input as a set signal S to STAGE(1). The output terminal of each stage is connected to its associated gate bus line 101G. Also, the output terminal of each of STAGE(2) through STAGE(N−1) is connected to the input terminal of a following stage that receives the set signal. In FIG. 2(a), lines VSS, CK1, CK1B, CK2, CK2B and CLR are trunk lines.

FIG. 2(b) is a plan view illustrating a much simplified version of the configuration shown in FIG. 2(a). As shown in FIG. 2(b), a trunk line area where the trunk lines are arranged, a shift register circuit area, and a pixel area (display area) are arranged in this order from one end of the panel toward its center. The trunk line area and the shift register circuit area will be collectively referred to herein as a “gate driver area”. In some panels, the gate driver areas are arranged on both sides of the pixel area.

Four gate clock signals CK1, CK1B, CK2 and CK2B, the gate start pulse signal GSP-O and a gate end pulse signal GEP-E are applied from a display controller (not shown) to the shift register 110A.

As can be seen from portions (a) through (d) of FIG. 3, the gate clock signals CK1 and CK1B have a phase difference of 180 degrees (i.e., a period corresponding to one horizontal scanning period) between them, so does the gate clock signals CK2 and CK2B. Also, the gate clock signal CK1 has a phase lead of 90 degrees with respect to the gate clock signal CK2. Likewise, the gate clock signal CK1B has a phase lead of 90 degrees with respect to the gate clock signal CK2B. Each of these gate clock signals goes high (rises to High level) every other horizontal scanning period.

When the gate start pulse signal GSP-O is applied as a set signal S to the first stage STAGE(1) of the shift register 110, the pulse included in the gate start pulse signal GSP-O (and will also be included in the output signal Q of each stage) is transferred sequentially from the first stage STAGE(1) through the last stage STAGE(N) in response to the gate clock signals CK1, CK1B, CK2 and CK2B. And every time this pulse is transferred from one stage to the next, the output signal Q of each of STAGE(1) through STAGE(N) goes high one after another. According to this preferred embodiment, the output signal Q to be delivered from an odd-numbered stage STAGE(1), STAGE(3), and so on shifts when the clock signal CK1 or CK1B goes high. On the other hand, the output signal Q to be delivered from an even-numbered stage STAGE(2), STAGE(4), and so on shifts when the clock signal CK2 or CK2B goes high.

In this manner, a scan signal (i.e., the output signal Q) that goes and stays high sequentially for one horizontal scanning period is applied to one gate bus line after another in the pixel area.

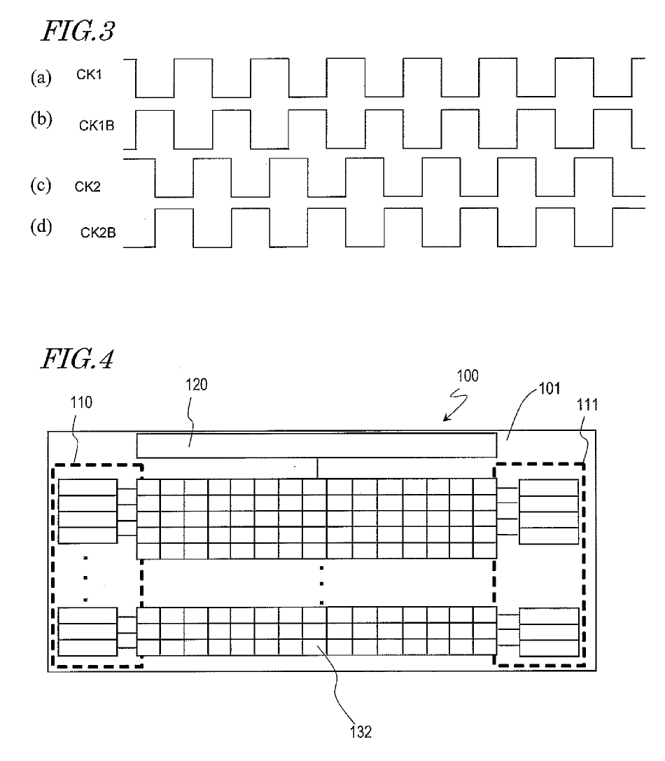

In the example illustrated in FIG. 1, the gate driver is supposed to be arranged only on one side of the pixel area. However, gate drivers 110 and 111 may be arranged on both sides of the pixel area as shown in FIG. 4. With the arrangement shown in FIG. 4, one gate bus line can be charged on both sides, i.e., with the respective outputs of the two shift registers. That is why when a big panel with a huge panel load needs to be driven, it is preferred that the gate drivers 110 and 111 be arranged on both sides of the pixel area.

Hereinafter, the configuration of a circuit provided for each single stage (on the Nth stage) of the shift register 110A will be described. First of all, the configuration of a circuit 10 with no TFTs for repair (corresponding to one stage of the shift register 110A) will be described as a comparative example with reference to FIG. 5.

As shown in FIG. 5, this circuit 10 includes thin-film transistors MA, MB, MI, MF, MJ, MK, ME, ML, MN and MD and a capacitor CAP1. It is preferred that the conductivity type of every one of these thin-film transistors (TFTs) be either p-type or n-type. Also, these TFTs are preferably amorphous silicon TFTs or microcrystalline silicon TFTs.

In this description, the line that is connected to the gate electrode of the thin-film transistor MI will be referred to herein as a “node N1”. In this circuit 10, the respective source terminals of the thin-film transistors ML and ME, the gate terminal of the thin-film transistor MJ and the source terminal of the thin-film transistor MB are connected to the node N1.

On the other hand, a line that discharges the node N1 when going high will be referred to herein as a “node N2”. In this circuit 10, the gate terminal of the thin-film transistor ME, the drain terminal of the thin-film transistor MF, and the respective source terminals of the thin-film transistors MK and MJ are connected to the node N2.

The thin-film transistor MB is an input TFT and raises the potential at the node N1 if the input signal S (that is the output of the previous stage of the shift register) is high.

The thin-film transistor MI is an output TFT and delivers CKA as an output signal Qn when the node N1 is high. In this description, the transistor MI that delivers the output signal Qn will sometimes be referred to herein as a “first transistor”. The thin-film transistor MI is a so-called “pull-up transistor”.

When CKC goes high, the thin-film transistor MF raises the potential at the node N2 to High level. Meanwhile, when the node N1 is at High level, the thin-film transistor MJ lowers the potential at the node N2 to Low level. When the potential at the node N2 goes high to turn the thin-film transistor ME ON at the time of output, sometimes the potential at the node N1 may go Low to turn the output TFT (i.e., the thin-film transistor MI) OFF. This thin-film transistor MJ can prevent the potential at the node N2 from going high at the time of output.

When CKD is high, the thin-film transistor MK lowers the potential at the N2 to Low. If it were not for the thin-film transistor MK, the potential at the node N2 would always be high except at the time of output and a bias voltage would be applied continuously to the thin-film transistor ME. In that case, the thin-film transistor ME might have its threshold value increased too much to function as a switch anymore.

When the node N2 is at High level, the thin-film transistor ME lowers the potential at the node N1 to Low level. When the reset signal R (i.e., the output of the next stage of the shift register) is high, the thin-film transistor ML lowers the potential at the node N1 to Low, while the thin-film transistor MN lowers the level of the output signal Qn to Low. The thin-film transistor MD lowers the level of the output signal Qn to Low synchronously with the inverted clock signal CKB of CKA.

The capacitor CAP1 is a compensating capacitor that always keeps the potential at the node N1 high. That is to say, without this capacitor, the potential at the node N1 would decrease.

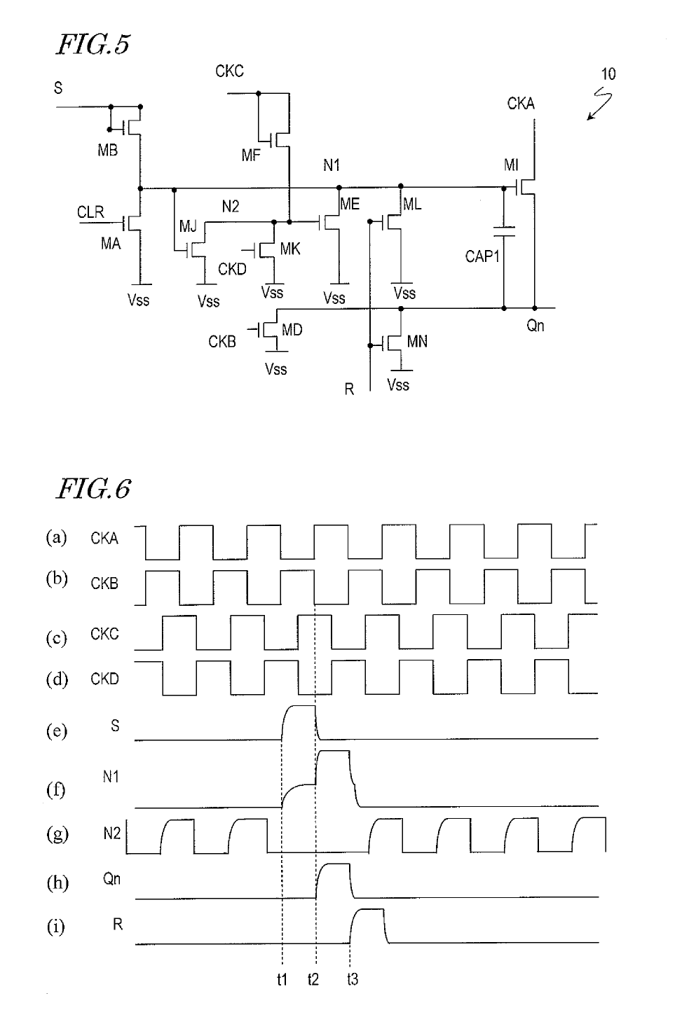

Hereinafter, it will be described with reference to FIGS. 5 and 6 generally how the circuit 10 operates. Portions (a) through (i) of FIG. 6 illustrate the waveforms of the input and output signals at respective stages of the shift register 110A along with the voltage waveforms at the nodes N1 and N2.

When the input signal S goes high (at a time t1), the node N1 is charged, while the potential at the node N2 decreases to Low level due to the action of the thin-film transistor MJ. As a result, the thin-film transistor ME turns OFF.

Next, when CKA goes high (at a time t2), the potential at the node N1 is boosted by the parasitic capacitance of the thin-film transistor MI and CKA is supplied to Qn. At this time, the potential at the node N2 is still low and the thin-film transistor ME is still in OFF state.

After that, when CKA goes low and the signal R of the next stage rises (at a time t3), the potential at the node N1 and the level of the output Qn both go low.

If a defect was caused in any of the TFTs that influence the operation of the shift register described above while the circuit 10 of the comparative example shown in FIG. 5 is being fabricated, then the defect could affect the operation of the shift register seriously to make the image on the screen of the panel defective.

Thus, to overcome such a problem, according to this preferred embodiment, a TFT for repair is provided for at least one of the TFTs on each stage of the shift register (the at least one TFT will be referred to herein as an “in-circuit TFT”). Then, even if that in-circuit TFT went defective, the shift register could still operate properly by disconnecting that defective in-circuit TFT from the circuit and by connecting the TFT for repair to the circuit instead. As a result, the production yield can be increased.

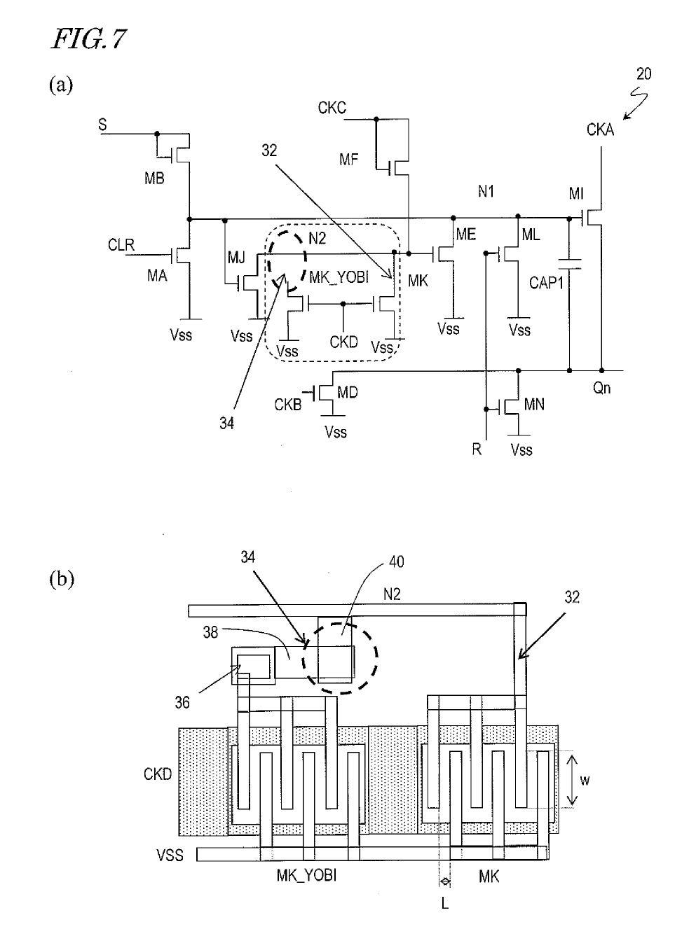

FIG. 7(a) illustrates an exemplary configuration for a circuit 20 including a TFT for repair on one stage of a shift register as a preferred embodiment of the present invention. FIG. 7(b) is a schematic plan view illustrating, on a larger scale, the dotted-line portion of the circuit 20 shown in FIG. 7(a) that includes the TFT for repair.

In this circuit 20, a thin-film transistor for repair MK_YOBI is provided for the thin-film transistor MK. In the thin-film transistor MK_YOBI, its gate electrode is connected to CKD, its drain electrode is connected to a VSS line, and its source electrode is connected through a contact hole 36 to a line 38 that is made of the same film as the gate line. The line 38 is floating and is arranged so as to intersect with a line (source line) 40, which is connected to the node N2 with an interlayer insulating film (not shown) interposed between them. The intersecting portion 34 between these lines 38 and 40 will be referred to herein as a “crossing portion”.

Also, as can be seen from FIG. 7(b), in each of the thin-film transistors MK and MK_YOBI of this preferred embodiment, a comb-shaped source electrode and a comb-shaped drain electrode are arranged on the channel region of a semiconductor layer with a gap left between them, and a number of channels are formed in that gap between the electrodes.

In the example illustrated in FIG. 7(b), five channels (each having a channel length L) have been formed. In this case, the channel length L refers to the distance between one branch of the source electrode and its associated branch of the drain electrode, which faces the former branch, and is usually within the range of 3 μm to 6 μm. Also, in these thin-film transistors, their effective channel width W (which will be simply referred to herein as a “channel which W”) is the sum of the widths w of the respective channels as measured perpendicularly to the channel direction. Specifically, since there are five channels each having a width w in this example, the channel width W becomes five times as long as the width w (i.e., W=w×5). It should be noted that the number of the channels to provide is not particularly limited. By choosing an appropriate number of channels to provide, the channel width W can be adjusted to any arbitrary value.

If a defect appears in the thin-film transistor MK of the circuit 20 during the manufacturing process of the gate driver monolithic panel (which will be simply referred to herein as a “panel”), then the thin-film transistor MK is disconnected from the node N2 and the thin-film transistor for repair MK_YOBI is connected to the node N2 instead. This point will be described in further detail below.

First of all, the rear and counter substrates of the panel are made by performing known manufacturing processing steps. In this example, pixel switching TFTs and pixel electrodes are formed in a portion of the rear substrate to be a display area, and a gate driver and other drivers are formed in another portion of the rear substrate to be a frame area. After that, these substrates are inspected for defects before being bonded together.

If any defect has been detected as a result of the inspection, the substrates are subjected to a repair process before being bonded together. In the repair process, the line 32 that connects the thin-film transistor MK to the source electrode and the node N2 is cut off with a laser beam, for example. Also, by irradiating the crossing portion 34 with a laser beam and melting it, the source electrode of the thin-film transistor for repair MK_YOBI and the node N2 are connected together. The processing step of cutting off the line 32 and the processing step of melting the crossing portion 34 may be performed in any order. As a result, the circuit 20 can now operate properly by using the thin-film transistor MK_YOBI instead of the thin-film transistor MK with a defect.

Thereafter, the rear and counter substrates that have been subjected to such a repair process are bonded together to complete a panel.

If no defect has appeared in the thin-film transistor MK, then no repair process will be carried out. In that event, the shift register completed will still have the configuration shown in FIGS. 7(a) and 7(b). On the other hand, if any defect has appeared in the thin-film transistor MK on at least one stage of the shift register being fabricated, then the repair process is carried out as described above. In that case, the shift register completed will have a stage including the thin-film transistor MK, of which the line 32 has been cut off and which has a floating terminal, and the thin-film transistor MK_YOBI, which is connected to the node N2 with the crossing portion 34 and which functions as an in-circuit TFT.

In the plan view illustrating this preferred embodiment, the crossing portion 34 preferably has a size of at least 10 μm×10 μm, for example, and more preferably has a size of 20 μm×20 μm or more. Then, the lines 40 and 38 can be connected together more securely through the melt treatment.

In the example illustrated in FIG. 7, a TFT for repair is provided for the thin-film transistor MK. However, a TFT for repair may also be provided for any other one of the TFTs that form the shift register. Among other things, the TFT for repair is preferably provided for a TFT with a narrow channel width W or a TFT, of which the number of channels has been reduced to decrease the channel width W. The reason will be described with reference to some of the drawings.

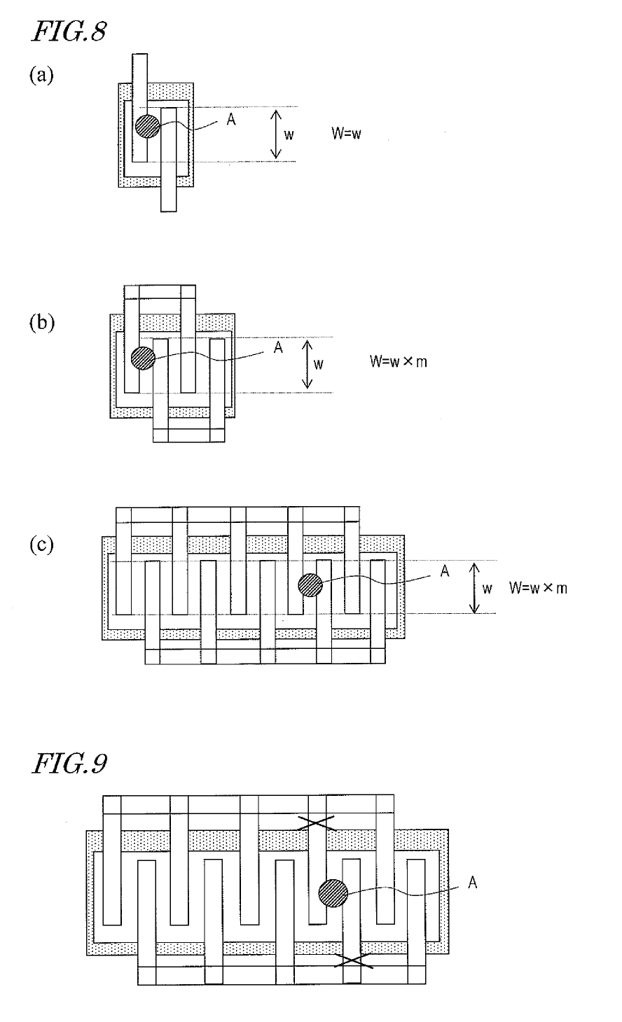

FIGS. 8(a) through 8(c) are plan views illustrating configurations for TFTs for use in the circuit 20 of this preferred embodiment.

FIG. 8(a) illustrates a configuration for a TFT with only one channel. Since there is only one channel, the width was measured perpendicularly to the channel direction of that channel becomes the channel width W (i.e., W=w). In such an arrangement, the channel width W if often set to be small (e.g., 50 μm or less). And if any defect A such as dust, leakage current or disconnection was caused in a part of the channel of this TFT, the device would no longer operate properly as a TFT. In that case, the shift register could not work anymore and a failure that would affect the entire panel might happen.

FIG. 8(b) illustrates a TFT with a small number of channels (which is typically two to five and is three in the illustrated example). Supposing the number of channels is m (where 2≦m≦5) and the width as measured perpendicularly to the channel direction of each channel is w, the channel width W is calculated by w×m. In this case, since the number of channels m is small, the channel width W is small in many cases. With such an arrangement, if any defect A such as dust, leakage current or disconnection was caused in one of the channels, then the drivability of that TFT would decrease significantly. In that case, the operation of the shift register could be disturbed seriously and a failure that would affect the entire panel might happen.

FIG. 8(c) illustrates a configuration for a TFT with a lot of channels (which is at least six and is nine in the illustrated example). As in the example just described, supposing the number of channels is m (where 6≦m) and the width as measured perpendicularly to the channel direction of each channel is w, the channel width W is also calculated by w×m. In this case, since the number of channels m is large, the channel width W is great (e.g., 500 μm or more) in many cases. With such an arrangement, even if any defect A such as dust, leakage current or disconnection was caused in one of the channels, the defect could be compensated for by another channel and the drivability of the TFT would not decrease so much. Also, even with no TFTs for repair provided, the repair can still be made by cutting off the branches of the source and drain electrodes that form the channel with the defect A as shown in FIG. 9.

As can be seen, if the number of channels of a TFT is m and if a defect A has appeared in one location, then the drivability of that TFT could decrease to almost the same level as that of a TFT, of which the number of channels is (m−3) (when subjected to the repair process shown in FIG. 9, for example). The smaller the number of channels m, the greater the impact of the defect A on the drivability of the TFT. That is why a TFT for repair is preferably provided for an in-circuit TFT with a small number of channels m (and often with a narrow channel width W). In such an in-circuit TFT, the number of channels m is preferably five or less and more preferably one. Then, the yield of the panels can be increased more effectively.

The point of connection and the point of disconnection to adopt in the repair process do not have to be the line 32 and the crossing portion 34 shown in FIG. 7, either. Rather, according to this preferred embodiment, at least one of the three terminals of the TFT for repair should be floating (such a terminal will be referred to herein as a “floating terminal”) to say the least. The extended portion of that floating terminal has been extended so much as to be connectible to a predetermined line. In this description, the “predetermined line” refers herein to a line, to which one terminal of the in-circuit TFT, corresponding to the floating terminal, is connected. On the other hand, the line to cut off has only to be a line that connects that terminal of the in-circuit TFT corresponding to the floating terminal to the predetermined line. It should be noted that if there are two floating terminals, there will be two points of connection and two points of disconnection.

In the following description, if an in-circuit TFT included in a shift register (which will be referred to herein as a “first TFT”) is provided with a TFT for repair (which will be referred to herein as a “second TFT”), the three terminals of the first TFT will be identified herein by 1A, 1B and 1C, respectively, and the three terminals of the second TFT will be identified herein by 2A, 2B and 2C, respectively. The terminals 2A, 2B and 2C of the second TFT respectively correspond to the terminals 1A, 1B and 1C of the first TFT.

It is preferred that the terminals 1B and 2B be formed by patterning the same conductor film (which will be referred to herein as a “first conductor film”) and that the terminals 1A, 1C, 2A and 2C be formed by patterning a different conductor film from the first conductor film (which will be referred to herein as a “second conductor film”). The first and second conductor films are two different layers, and may or may not be made of the same material. For example, the terminals 1B and 2B may be made of a Ti/Al alloy and the terminals 1A, 1C, 2A and 2C may also be made of a Ti/Al alloy.

According to this preferred embodiment, before subjected to the repair process, at least one of the three terminals of the second TFT may be floating and the other terminal(s) thereof may be connected to its/their corresponding terminal(s) of the first TFT. Specifically, two of the three terminals of the second TFT may be connected to their corresponding terminals of the first TFT and the other terminal thereof may be floating (such a situation will be referred to herein as “Case I”). Or only one of the three terminals of the second TFT may be connected to its corresponding terminal of the first TFT and the other two terminals thereof may be floating (such a situation will be referred to herein as “Case II”). According to the present invention, Case I is preferred to Case II because in Case I, there is only one point of connection to be made by the repair process and defects that could be caused through the repair process can be reduced.

In Case I, it is preferred that the terminals 2B and 1B and the terminals 2C and 1C be connected together in advance (i.e., before subjected to the repair process) and that the terminal 2A be floating. On the other hand, in Case II, it is preferred that the terminals 2C and 1C be connected together in advance and the other terminals 2A and 2B be floating.

In any of these cases, it is preferably determined in the order of priority (terminal X1→X2→X3) which of the three terminals of the second TFT should be floating.

First, if the second TFT has a terminal X1 to be connected to the internal node N1 or N2 of the shift register, then that terminal X1 should be made to float before the repair process so as to be connectible to the internal node N1 or N2 through the repair process. This is preferred because if the terminal X1 that is not floating were connected to the internal node and were not subjected to the repair process (i.e., if no defect appeared), then a huge additional capacitance would be produced at the node to cause the shift register to oscillate easily.

Next, if the second TFT has a terminal X2 to be connected to the output node Qn of the shift register, then that terminal X2 should be made to float before the repair process so as to be connectible to the output node Qn of the shift register through the repair process. This is preferred because if the terminal X2 that is not floating were connected to the output node Qn and were not subjected to the repair process, then a huge additional capacitance would be produced at the output node Qn to possibly blunt the output waveform.

Furthermore, if the second TFT has a terminal X3, which does not have to have a contact portion to form a crossing portion for connection when made to float, then that terminal X3 should be made to float to form the crossing portion. This should be done because if the number of contact portions increased, the resistance of the circuit would also increase, which could slow down the operation of the shift register.

According to this preferred embodiment, if the terminal 2A made of the second conductor film is made to float, then the terminal 2A may be connected to a line that is made of the first conductor film by way of the contact portion, thereby forming an extended portion of the terminal 2A that has a part made of the second conductor film and another part made of the first conductor film. In that case, the crossing portion may be designed so that that part of the extended portion of the terminal 2A, which is made of the first conductor film, and the extended portion of the terminal 1A, which is made of the second conductor film, overlap with each other without being connected together. Alternatively, the crossing portion may also be designed so that respective extended portions of the terminals 1A and 2A, which are made of the first and second conductor films, respectively, overlap with each other without being connected together.

Meanwhile, it is preferred that the terminal 1A of the first TFT, corresponding to the terminal 2A, be extended so as to be cut easily. Although not particularly limited, the length of the extended portion may be 100 μm or more. In the example illustrated in FIG. 7, the length of the extended portion of the terminal 1A means the length of the line 32 that connects the source electrode to the node N2.

The relative positions of the first and second TFTs are not particularly limited. But the second TFT may be located at such a position that the first TFT will reach when translated in either the x or y direction on the panel. In this description, the x and y directions on the panel refer herein to two orthogonal directions, which typically correspond to the row and column directions of pixels that are arranged. Alternatively, the second TFT may also be located at such a position that the first TFT will reach when rotated 90 degrees and translated in either the x or y direction on the panel. It is preferred that no other TFTs be interposed between the first and second TFTs.

The circuit 20 does not have to have the configuration shown in FIG. 7. For example, the thin-film transistor MF may be replaced with a capacitor that is arranged between CKC and the node N2. Optionally, as disclosed in Japanese Patent Application No. 2008-297297 that was filed by the applicant of the present application, the thin-film transistors ME and ML or ME, ML and MB may have a multi-channel arrangement. Then, the amount of leakage current that could flow through the node N1 can be eliminated effectively. The disclosure of Japanese Patent Application No. 2008-297297 is hereby incorporated by reference.

Also, although a shift register to be driven with quadrature phase clock signals has been described as an example, this preferred embodiment is applicable to any shift register, no matter what configuration or driving method the shift register adopts.

### Embodiment 2

Hereinafter, a second preferred embodiment of a shift register according to the present invention will be described with reference to the accompanying drawings. According to this preferred embodiment, among multiple TFTs that form the shift register, a TFT for repair is provided for a diode-connected TFT, which is a major difference from the first preferred embodiment of the present invention described above. The “diode-connected TFT” refers herein to a TFT, of which the gate electrode and the source or drain electrode are connected together and which is also called a “three-terminal diode”.

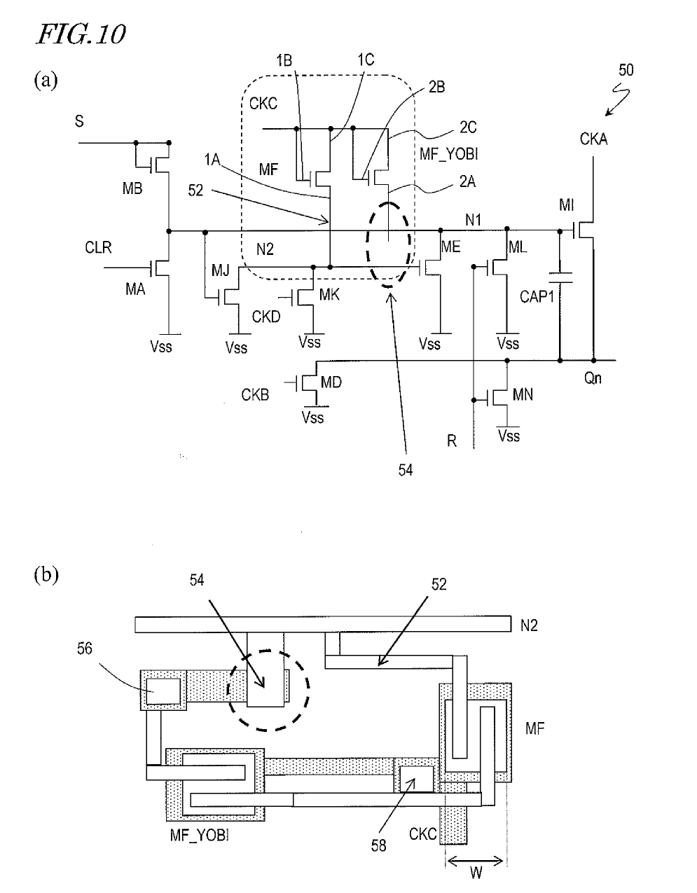

FIG. 10(a) illustrates an exemplary configuration for a circuit 50, including a TFT for repair, on one stage of a shift register according to this second preferred embodiment of the present invention. FIG. 10(b) is a schematic plan view illustrating, on a larger scale, the dotted-line portion of the circuit 50 shown in FIG. 10(a) that includes the TFT for repair.

In this circuit 50, a thin-film transistor for repair MF_YOBI is provided for a thin-film transistor MF. As a thin-film transistor MB is also diode-connected, a similar TFT for repair could be provided for the thin-film transistor MB, too. But as the thin-film transistor MF is smaller than the thin-film transistor MB that is an input TFT, more significant effects will be achieved by providing a TFT for repair for the thin-film transistor MF. Thus, in the exemplary circuit to be described below, a TFT for repair is supposed to be provided for the thin-film transistor MF.

If the three terminals of the thin-film transistor MF are identified by 1A, 1B and 1C, respectively, the terminal 1B (gate terminal) and the terminal 1C of the thin-film transistor MF are connected together through a contact hole 58. In the example illustrated in FIG. 10, the terminal 1A is connected to a node N2. The terminals 1C and 1A are made of the same conductor film (i.e., the second conductor film), and the terminal 1B is made of a different conductor film from the second conductor film (i.e., the first conductor film). The first and second conductor films are two different layers, and may be made of different materials.

On the other hand, if the three terminals of the thin-film transistor MF_YOBI are identified by 2A, 2B and 2C, respectively, the terminal 2B (gate terminal) and the terminal 2C are connected together. The terminal 2B is also connected to the terminal 1B of the thin-film transistor and the terminal 2C is also connected to the terminal 1C of the thin-film transistor. Meanwhile, the terminal 2A is floating.

The terminal 2A (which is made of the second conductor film) is connected to a line that is made of the first conductor film by way of a contact portion. As a result, an extended portion of the terminal 2A, including two parts that are made of the first and second conductor films, respectively, is formed. That part of the extended portion of the terminal 2A, which is made of the first conductor film, and the extended portion of the terminal 1A, which is made of the second conductor film, are arranged so as to overlap with each other with an interlayer insulating film (not shown) interposed between them. Such a portion 54 where the two extended portions overlap with each other will be referred to herein as a “crossing portion”.

Also, as can be seen from FIG. 10(b), the thin-film transistors MF and MF_YOBI of this preferred embodiment have only one channel, and therefore, have a narrow channel width W. Although the number of channels is not particularly limited, more significant effects can be achieved by providing a TFT for repair for an in-circuit TFT with a small number of (e.g., five or less) channels as already described for the first preferred embodiment of the present invention.

If a defect appears in the thin-film transistor MF of the circuit 50 during the manufacturing process of the gate driver monolithic panel (which will be simply referred to herein as a “panel”), then the thin-film transistor MF is disconnected from the node N2 and the floating terminal 2A of the thin-film transistor for repair MF_YOBI is connected to the node N2 instead. This point will be described in further detail below.

First of all, the rear and counter substrates of the panel are made by performing known manufacturing processing steps. In this example, pixel switching TFTs and pixel electrodes are formed in a portion of the rear substrate to be a display area, and a gate driver and other drivers are formed in another portion of the rear substrate to be a frame area. After that, these substrates are inspected for defects before being bonded together.

If any defect has been detected as a result of the inspection, the substrates are subjected to a repair process before being bonded together. In the repair process, the line 52 that connects the thin-film transistor MF to the source electrode and the node N2 is cut off with a laser beam, for example. Also, by irradiating the crossing portion 54 with a laser beam and melting it, the source electrode of the thin-film transistor for repair MF_YOBI and the node N2 are connected together. The processing step of cutting off the line 52 and the processing step of melting the crossing portion 54 may be performed in any order. As a result, the circuit 50 can now operate properly by using the thin-film transistor MF_YOBI instead of the thin-film transistor MF with a defect.

Thereafter, the rear and counter substrates that have been subjected to such a repair process are bonded together to complete a panel.

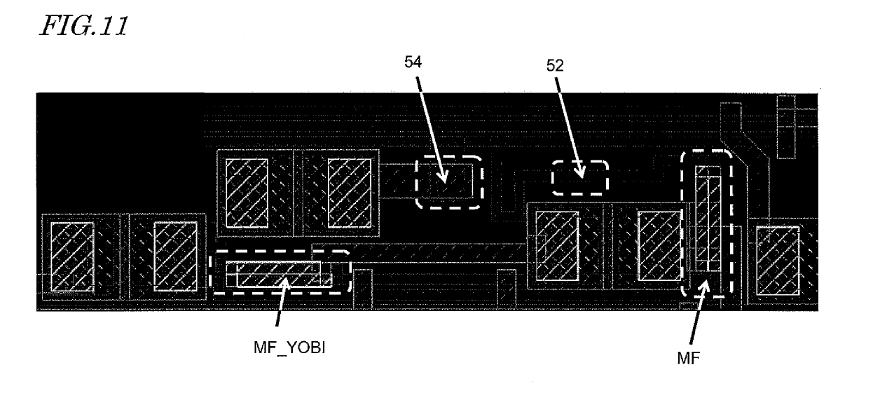

FIG. 11 illustrates the layout of a portion of the circuit 50. As already described with reference to FIG. 10, if the thin-film transistor MF has a defect, then the line 52 is cut off to disconnect the thin-film transistor MF from the circuit 50 of the shift register. Instead, the crossing portion 54 is melted with a laser beam, for example, thereby connecting the thin-film transistor MF_YOBI to the circuit 50.

### INDUSTRIAL APPLICABILITY

The semiconductor element of the present invention is broadly applicable for use in any of various kinds of circuits and devices that ever have a shift register. Among other things, the present invention is applicable particularly effectively to various devices that use a thin-film transistor. Examples of such devices include circuit boards such as an active-matrix substrate, display devices such as a liquid crystal display, an organic electroluminescence (EL) display, and an inorganic electroluminescence display, image capture devices such as a flatpanel X-ray image sensor, and electronic devices such as an image input device and a fingerprint scanner.

### REFERENCE SIGNS LIST

110A shift register
10 circuit representing comparative example included in one stage of shift register
20, 50 circuit included in one stage of shift register
32, 52 portion to be cut off by repair process
34, 54 portion to be connected by repair process
36, 56, 58 contact hole
40 line
N1, N2 node
MA, MB, MD, ME, MF, MI, MJ, MK, ML, MN in-circuit TFT
MK_YOBI TFT for repair for thin-film transistor MK

1. A shift register that is supported on an insulating substrate and that has multiple stages that sequentially shift an output signal from one stage to the next, each said stage having a circuit including multiple thin-film transistors, wherein the multiple thin-film transistors comprise:
a first thin-film transistor, which influences the operation of the circuit; and
a second thin-film transistor, which has at least one floating terminal and other terminal(s) that is/are connected to corresponding terminal(s) of the first thin-film transistor, the at least one floating terminal being arranged so as to be connectible to a predetermined line.

2. The shift register of claim 1, wherein when viewed from over the substrate, the channel regions of the first and second thin-film transistors have substantially the same shape.

3. The shift register of claim 1, wherein the first and second thin-film transistors have a structure in which one of their source and drain electrodes is connected to their gate electrode, the other of the source and drain electrodes of the second thin-film transistor floating.

4. The shift register of claim 1, wherein an extended portion of the at least one floating terminal of the second thin-film transistor and an extended portion of a terminal of the first thin-film transistor, which corresponds to the floating terminal, overlap with each other without being connected together.

5. The shift register of claim 4, wherein when viewed from over the substrate, the size of the overlapping portion is bigger than 10 μm×10 μm.

6. The shift register of claim 1, wherein if the three terminals of the first thin-film transistor are identified by 1A, 1B and 1C, respectively, the three terminals of the second thin-film transistor are identified by 2A, 2B and 2C, respectively, and the terminals 2A, 2B and 2C correspond to the terminals 1A, 1B and 1C, respectively, then the terminals 2A, 1A, 1C and 2C are made of a first conductor film, the terminals 2B and 1B are made of a second conductor film, which is different from the first conductor film, and at least the terminal 2C is connected to the terminal 1C.

7. The shift register of claim 6, wherein the terminal 2B is connected to the terminal 1B.

8. The shift register of claim 1, wherein no other thin-film transistors are interposed between the first and second thin-film transistors.

9. The shift register of claim 1, wherein the first and second thin-film transistors have the same number of channels, which is equal to or smaller than five.

10. The shift register of claim 9, wherein the number of the channels is one.

11. The shift register of claim 1, wherein a terminal of the first thin-film transistor that corresponds to the floating terminal has an extended portion, which has a length of 100 μm or more.

12. A shift register that is supported on an insulating substrate and that has multiple stages, which sequentially shift an output signal from one stage to the next and at least one of which has a circuit including multiple thin-film transistors, wherein the multiple thin-film transistors comprise:
a thin-film transistor M1, which influences the operation of the circuit; and
a thin-film transistor M2, which has at least one floating terminal and other terminal(s) that is/are connected to corresponding terminal(s) of the thin-film transistor M1, and
wherein an extended portion of that terminal of the thin-film transistor M1 that corresponds to the floating terminal overlaps with a predetermined line, and the overlapping portion has been subjected to a melt treatment, thereby connecting the extended portion of the thin-film transistor M1 and the predetermined line together.

13. An active-matrix substrate comprising the shift register of claim 1.

14. A display panel comprising the shift register of claim 1.

15. A method for fabricating the shift register of claim 4, the method comprising the steps of:
inspecting the first thin-film transistor of the circuit for defects; and
if any defect has been detected in the step of inspecting,
performing a repair process by disconnecting the first thin-film transistor from the circuit and by connecting the floating terminal of the second thin-film transistor to a predetermined line of the circuit,
wherein the repair process includes subjecting the overlapping portion to a melt treatment and connecting the floating terminal of the second thin-film transistor to the predetermined line.
